(19) United States
(12) Patent Application Publication
(10) Pub. No.: US 2005/0189611 A1
(43) Pub. Date: Sep. 1, 2005

(54) High frequency passive element

(75) Inventor: Satoshi Makioka, Otsu-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/034,218

(22) Filed: Jan. 13, 2005

(30) Foreign Application Priority Data
Jan. 14, 2004 (JP) 2004-006705

(51) Int. Cl. H01L 29/00

(52) U.S. Cl. 257/528

(57) ABSTRACT

An insulator layer is fabricated that is composed of a large number of insulating ridges formed with predetermined mutual spacing on a Si substrate. Then, an inductor conductor layer is formed in a spiral or swirl pattern on the insulator layer. An outgoing wiring conductor layer is provided between the Si substrate and the insulator layer, while a via hole is provided in the insulator layer immediately under the center-side end portion of the spiral or swirl of the inductor conductor layer, so that the center-side end portion of the spiral or swirl of the inductor conductor layer is connected to the outgoing wiring conductor layer through the via hole.

### BACKGROUND OF THE INVENTION

1. Field of the Invention

The present invention relates to a high frequency passive element formed on a substrate such as a semiconductor substrate. In particular, the invention is applicable to a low loss configuration of a high frequency passive element in a microwave monolithic IC (MMIC, hereafter).

2. Prior Art

In semiconductor devices represented by MMICs or the like, miniaturization and high density mounting are progressing year by year. In particular, wirings and passive elements such as inductors which constitute a semiconductor device occupy a large portion of the area of the semiconductor device. Thus, further miniaturization and high density mounting of these wirings and passive elements are desired.

A spiral inductor is a kind of a planar type inductance element, and used as a circuit element of an MMIC, for the purpose of impedance matching or high-frequency choke coil use. Planar type inductance elements other than the spiral inductor described here include a high impedance line and a meander line.

In a straight line (high impedance line), achievable inductance is rather restricted owing to the limit in the line width which can be fabricated. Accordingly, necessary area increases for achieving a higher inductance. On the other hand, in a meander line, when a smaller area is pursued, a coupling occurs due to a negative mutual inductance between adjacent lines. Thus, necessary area increases for achieving a desired inductance. As such, these latter two inductance elements have a disadvantage. In contrast, the spiral inductor having been described first is effective in achieving a high inductance with a small area.

In general, in the configuration of a spiral inductor employing a Si substrate (a semiconductor substrate), the inductor is wired around in a second layer wiring (Au plating), and then pulled out as an outgoing wiring to the outside at its central end portion through a first layer wiring which intersecting with the second layer wiring or through an air bridges.

FIG. 6A is a plan view of a prior art spiral inductor viewed from the above. FIG. 6B is a sectional view taken along line D-D′ of FIG. 6A. In the wirings of the prior art spiral inductor, that is, the wiring formed in the first conductor layer and the wiring formed in the second conductor layer, their wiring width is 5 microns each, the wiring height is 1 micron each, and the wiring interval is 5 microns each.

This spiral inductor is fabricated as follows. First, as shown in FIGS. 6A and 6B, a Ti/Pt/Au is formed as a first wiring metal 2 on the principal surface of a Si substrate 5 by vapor deposition. Then, a SiN layer is formed as an insulation film 9. After that, a via hole 3 is formed. Then, a second wiring metal 1 is formed in a spiral (swirl) shape by Au plating, and then connected through the via hole 3 to the first wiring metal 2 serving as an outgoing wiring.

In FIG. 6, numeral 6 indicates a ground conductor layer formed on the back surface of the Si substrate 5.
Patent Document 1: JP-A-2000-021635
Patent Document 2: JP-A-2001-223331

In the prior art configuration, Si substrate 5 has an electric conductivity of approximately 0.1-100 Ωcm. Accordingly, in the spiral inductor, the second wiring metal 1 serves as a parasitic capacitance through the insulation film (dielectric) 9 so as to reduce the Q factor.

In Patent Documents 1 and 2 cited as the prior art, a cavity is provided in the silicon substrate so that a mutual induction effect is suppressed in the carriers in silicon, and that the effective dielectric constant of the silicon is reduced. However, these prior art techniques have several problems as follows. That is, a deep groove is necessary for achieving a sufficient effect. Further, when an oxide film is used for covering and filling the cavity, a large level difference occurs in the surface owing to the problem of coverage. Furthermore, the process becomes complicated.

### SUMMARY OF THE INVENTION

An object of the invention is to provide a high frequency passive element capable of reducing a parasitic capacitance.

The invention provides a configuration which reduces a parasitic capacitance in a spiral inductor and improves its Q factor. The invention is not limited to the spiral inductor, and is applicable to an MIM (metal-insulator-metal) capacitor and a resistor so as to reduce their parasitic capacitance.

In order to resolve the above-mentioned problems, a high frequency passive element according to the invention comprises: a substrate; an insulator layer composed of a single number or a plurality of insulating ridges or a plurality of insulating protrusions formed with predetermined mutual spacing on the substrate; and a passive element layer formed on the insulator layer.

According to this configuration, the insulator layer present between the substrate and the passive element layer is composed of a single number or a plurality of insulating ridges or a plurality of insulating protrusions formed with predetermined mutual spacing. Accordingly, the effective dielectric constant of the insulator layer becomes smaller than the original value in the insulator layer. This suppresses a parasitic capacitance generated by the insulator layer serving as a dielectric and the passive element layer serving as an electrode, and hence suppresses a decrease in the Q factor due to the presence of the parasitic capacitance.

In a first example, the passive element layer is composed of an inductor conductor layer formed in a spiral or swirl pattern on the insulator layer. In this case, the high frequency passive element constitutes a spiral inductor.

According to this configuration, the insulator layer present between the substrate and the inductor conductor layer is composed of a single number or a plurality of insulating ridges or a plurality of insulating protrusions formed with predetermined mutual spacing. Accordingly, the effective dielectric constant of the insulator layer becomes smaller than the original value in the insulator layer. This suppresses a parasitic capacitance generated by the insulator layer serving as a dielectric and the inductor conductor layer serving as an electrode, and hence suppresses a decrease in the Q factor due to the presence of the parasitic capacitance.

In this configuration, in a preferred example, an outgoing wiring conductor layer is provided between the substrate and the insulator layer, while a via hole is provided in the insulator layer immediately under the center-side end portion of the spiral or swirl of the inductor conductor layer, so that the center-side end portion of the spiral or swirl of the inductor conductor layer is connected to the outgoing wiring conductor layer through the via hole.

According to this configuration, the wiring is easily pulled out from the center portion of the inductor conductor layer.

Further, in this high frequency passive element, a single number or a plurality of the insulating ridges or a plurality of the insulating protrusions constituting the insulator layer are preferably arranged in a radial manner extending from the center of the spiral or swirl of the inductor conductor layer toward the periphery.

This configuration suppresses a disturbance in the electromagnetic field in the insulator layer serving as a lower dielectric, and hence improves the characteristics.

Further, in the high frequency passive element, a single number or a plurality of the insulating ridges or a plurality of the insulating protrusions constituting the insulator layer are preferably formed along an end face of said inductor conductor layer with maintaining a predetermined distance from the end face of said inductor conductor layer.

According to this configuration, the insulator layer is kept away from a portion where the electric field is concentrated owing to a skin effect. This reduces the influence of the insulator layer serving as a lower dielectric, and hence improves the characteristics.

In a second example, the passive element layer comprises: a capacitor lower electrode conductor layer formed on the insulator layer; a capacitor dielectric layer formed on the capacitor lower electrode conductor layer; and a capacitor upper electrode conductor layer formed on the capacitor dielectric layer. In this case, the high frequency passive element constitutes a capacitor.

According to this configuration, the insulator layer present between the substrate and the capacitor lower electrode conductor layer is composed of a single number or a plurality of insulating ridges or a plurality of insulating protrusions formed with predetermined mutual spacing. Accordingly, the effective dielectric constant of the insulator layer becomes smaller than the original value in the insulator layer. This suppresses a parasitic capacitance generated by the insulator layer serving as a dielectric and the capacitor lower electrode conductor layer serving as an electrode.

In this configuration, a single number or a plurality of the insulating ridges or a plurality of the insulating protrusions constituting the insulator layer are preferably arranged in a radial manner extending from the center of the capacitor lower electrode conductor layer toward the periphery.

This configuration suppresses a disturbance in the electromagnetic field in the insulator layer serving as a lower dielectric, and hence improves the characteristics.

In this configuration, a single number or a plurality of the insulating ridges or a plurality of the insulating protrusions constituting the insulator layer are preferably formed along an end face of the capacitor lower electrode conductor layer with maintaining a predetermined distance from the end face of the capacitor lower electrode conductor layer.

According to this configuration, the insulator layer is kept away from a portion where the electric field is concentrated owing to a skin effect. This reduces the influence of the insulator layer serving as a lower dielectric, and hence improves the characteristics.

In a third example, the passive element layer is composed of a resistive conductor layer formed on the insulator layer. In this case, the high frequency passive element constitutes a resistor.

According to this configuration, the insulator layer present between the substrate and the resistive conductor layer is composed of a single number or a plurality of insulating ridges or a plurality of insulating protrusions formed with predetermined mutual spacing. Accordingly, the effective dielectric constant of the insulator layer becomes smaller than the original value in the insulator layer. This suppresses a parasitic capacitance generated by the insulator layer serving as a dielectric and the resistive conductor layer serving as an electrode.

In this configuration, a single number or a plurality of the insulating ridges or a plurality of the insulating protrusions constituting the insulator layer are preferably arranged in a radial manner extending from the center of the resistive conductor layer toward the periphery.

This configuration suppresses a disturbance in the electromagnetic field in the insulator layer serving as a lower dielectric, and hence improves the characteristics.

In this configuration, a single number or a plurality of the insulating ridges or a plurality of the insulating protrusions constituting the insulator layer are preferably formed along an end face of the resistive conductor layer with maintaining a predetermined distance from the end face of the resistive conductor layer.

According to this configuration, the insulator layer is kept away from a portion where the electric field is concentrated owing to a skin effect. This reduces the influence of the insulator layer serving as a lower dielectric, and hence improves the characteristics.

In the above-mentioned configurations according to the invention, a single number or a plurality of the insulating ridges or a plurality of the insulating protrusions constituting the insulator layer preferably have such a cross sectional shape that a pedestal portion is narrow and that a tip portion is wide.

This configuration improves the retention adhesion property of the inductor conductor layer, the capacitor lower electrode conductor layer, or the resistive conductor layer. Further, these configurations reduce the influence of the insulator layer serving as a lower dielectric, and hence improve the characteristics.

Further, in the configurations according to the invention, a single number or a plurality of the insulating ridges or a plurality of the insulating protrusions constituting the insulator layer are preferably formed from Si nano crystals.

As mentioned above, in the high frequency passive element according to the invention, the insulator layer formed on the substrate is composed of a single number or a plurality of insulating ridges or a plurality of insulating protrusions formed with predetermined mutual spacing. This configuration easily reduces a parasitic capacitance generated by the insulator layer serving as a dielectric, and further realizes sufficient mechanical strength.

### BRIEF DESCRIPTION OF THE DRAWINGS

FIG. 1A is a plan view showing the configuration of a spiral inductor serving as a high frequency passive element according to Embodiment 1 of the invention.

FIG. 1B is a sectional view taken along line A-A′ of FIG. 1A.

FIG. 2 is a process-ordered sectional view showing the manufacturing process of a spiral inductor according to Embodiment 1 of the invention.

FIG. 3A is a plan view showing the configuration of an MIM (metal-insulator-metal) capacitor serving as a high frequency passive element according to Embodiment 2 of the invention.

FIG. 3B is a sectional view taken along line B-B′ of FIG. 3A.

FIG. 4A is a plan view showing the configuration of a resistor serving as a high frequency passive element according to Embodiment 3 of the invention.

FIG. 4B is a sectional view taken along line C-C′ of FIG. 4A.

FIG. 5 is a sectional view showing an insulator layer etched into an overhung inverted trapezoid shape.

FIG. 6A is a plan view showing the configuration of a prior art spiral inductor.

FIG. 6B is a sectional view taken along line D-D′ of FIG. 6A.

FIG. 7A is a plan view showing another example of the configuration of a spiral inductor serving as a high frequency passive element according to Embodiment 1 of the invention.

FIG. 7B is a sectional view taken along line E-E′ of FIG. 7A.

### DESCRIPTION OF THE PREFERRED EMBODIMENTS

### Embodiment 1

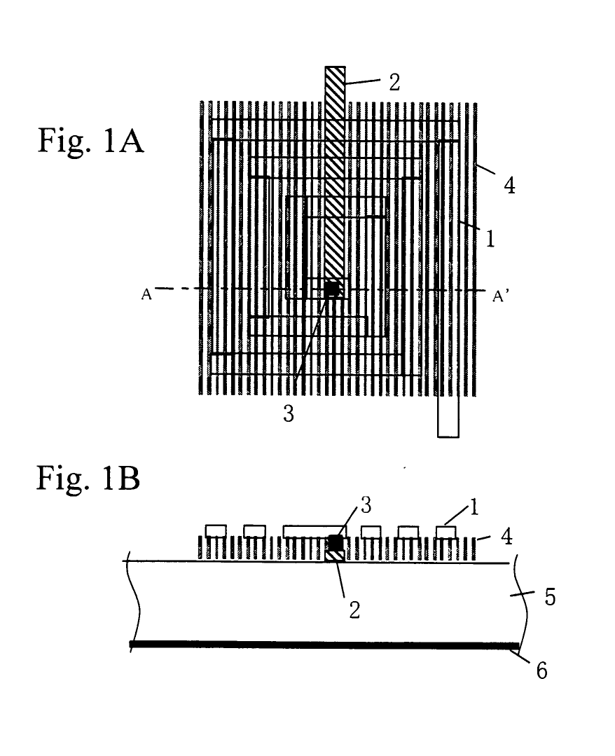

Embodiment 1 of the invention is described below in detail with reference to FIGS. 1A and 1B.

FIG. 1A is a plan view showing an example of a spiral inductor (high frequency passive element) according to Embodiment 1 of the invention, viewed from the above. FIG. 1B is a sectional view taken along line A-A′ of FIG. 1A.

As shown in FIGS. 1A and 1B, in this spiral inductor, an outgoing wiring (outgoing wiring conductor layer) composed of Ti/Pt/Au is formed as a first wiring metal layer 2 on a principal surface of a Si substrate 5 by vapor deposition. An insulator layer (insulation film) 4 composed of a SiN layer is formed on the first wiring metal layer 2. On the insulator layer 4, an inductor conductor layer is formed as a second wiring metal layer 1 by Au plating. The inductor conductor layer is formed in a spiral or swirl pattern, and constitutes a spiral inductor.

The insulator layer 4 is composed of a large number of line-shaped insulating ridges formed with predetermined mutual spacing on the Si substrate 5. These insulating ridges are arranged in parallel to each other.

The second wiring metal layer 1 and the outgoing wiring formed as the first wiring metal layer 2 are connected to each other at the center of the spiral through a via hole 3 which is a hole pierced in the insulator layer 4. That is, the via hole 3 is provided in the insulator layer 4 immediately under the center-side end portion of the spiral or swirl of the inductor conductor layer. Then, the center-side end portion of the spiral or swirl of the inductor conductor layer is connected to the outgoing wiring conductor layer through the via hole 3. In FIG. 1B, numeral 6 indicates a ground conductor layer formed on the back surface of the Si substrate 5.

In FIG. 1, the insulator layer 4 is composed of a large number of insulating ridges arranged mutually in parallel with predetermined spacing. Alternatively, the insulator layer may be composed of a large number of insulating protrusions arranged in two dimensions with predetermined mutual spacing. Further, the insulator layer 4 may be composed of a single number or a plurality of insulating ridges in meandering arrangement (zigzag arrangement).

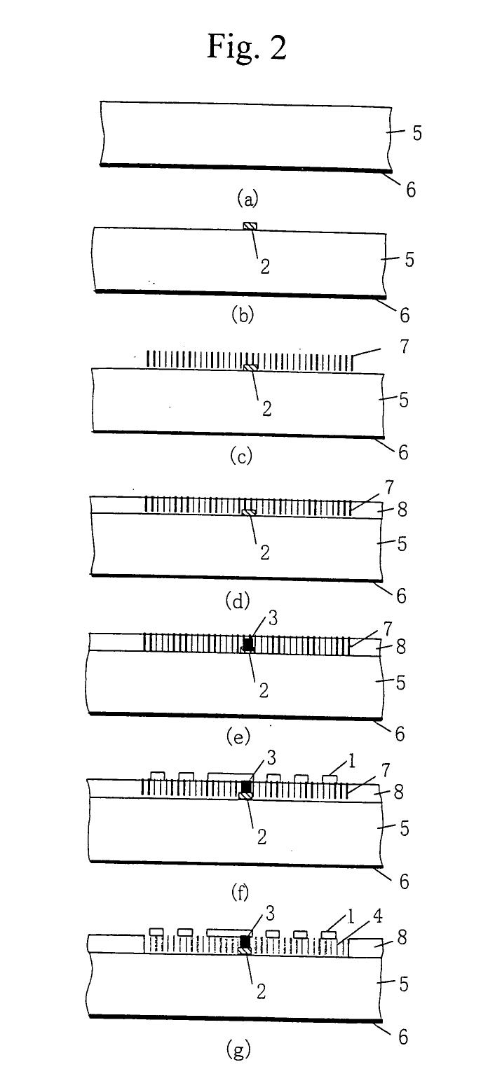

FIG. 2 is a process-ordered sectional view showing a manufacturing method for a spiral inductor of the present embodiment. The manufacturing method is described below with reference to FIG. 2.

First, as shown in FIG. 2(a), a Si substrate 5 is prepared that has a ground conductor layer 6 on its back surface. Then, as shown in FIG. 2(b), a first wiring metal layer 2 composed of Ti/Pt/Au and serving as an outgoing wiring conductor layer of a spiral inductor is formed on a Si substrate 5 by vapor deposition.

Then, as shown in FIG. 2(c), a resist 7 having a shape of notably narrow slits is formed by a phase shift exposure method, an EB exposure method, or the like. This process is the same as a fabrication process for a multi-fingered gate generally used in RF power FETs. This process generally allows the formation to be carried out in a submicron width (such as 0.2 μm) and a narrow pitch (such as 0.6 μm). A deeper channel depth of the slits (comb) increases a reduction effect in the effective dielectric constant. This channel depth of the slits (comb) is determined by the conditions of (resist) removal by etching in the next step.

Then, as shown in FIG. 2(d), an insulation film 8 such as SiO₂ and SiN having a small dielectric constant is formed on the resist 7 by TEOS or the like in a such a manner that the resist is exactly covered. At that time, the surface is etched by dry etching or the like until the upper portion of the resist 7 is exposed.

Then, as shown in FIG. 2(e), a via hole 3 is formed immediately on top of the first wiring metal layer 2. Then, a metal is embedded in the via hole 3.

Then, as shown in FIG. 2(f), a second wiring metal layer 1 is formed by Au plating, and processed into a spiral pattern. This second wiring metal layer 1 functions as the spiral inductor. This pattern processing of the second wiring metal layer 1 is carried out such that the position immediately on top of the via hole 3 corresponds to the center-side end portion of the spiral inductor.

Then, as shown in FIG. 2(g), the resist 7 is removed by wet etching. As a result, an inductor conductor layer constituting the spiral inductor lies on the insulator layer 4 which is composed of a large number of insulating ridges arranged in parallel to each other so as to form slits between the insulating ridges.

The present embodiment has been described for the case of a spiral inductor formed on the Si substrate 5. However, the spiral inductor may be formed on another semiconductor substrate (such as SiGe, GaAs, and GaN), a ceramic substrate (such as alumina), or a resin substrate.

In the present embodiment, the outgoing wiring layer and the inductor conductor layer are composed of metallic wirings such as Ti/Pt/Au and Au plating. However, another conductor metal may be used so that the same effect is obtained.

Similarly, the insulator layer 4 may be composed of another dielectric material so that the same effect is obtained.

In the present embodiment, the insulating ridges are arranged in parallel to each other. When the insulating ridges are arranged in a radial manner extending from the center portion of the high frequency passive element toward the periphery, a disturbance is reduced in the electromagnetic field in the insulator layer serving as a lower dielectric, so that the characteristics is improved.

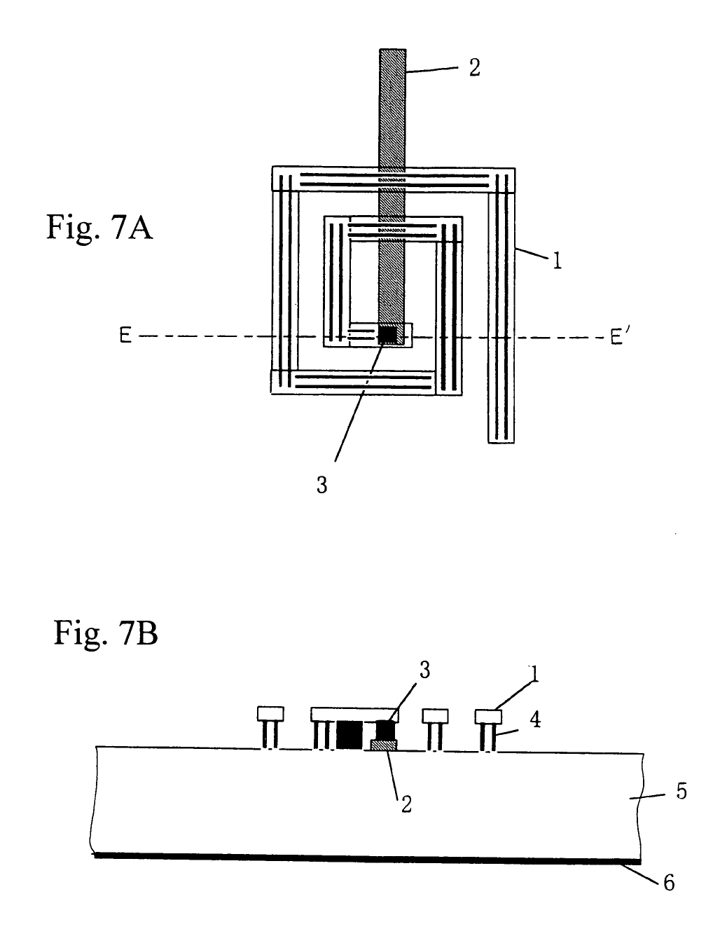

In the present embodiment, the insulating ridges constituting the insulator layer 4 are arranged in parallel to each other. However, for example, as shown in FIGS. 7A and 7B, the insulating ridges may be formed along an end face of the metal thereon (that is, the second wiring metal layer 1) with maintaining a predetermined distance from the end face of the metal. When constructed in this manner, the insulating ridges are kept away from a portion where the electric field is concentrated owing to a skin effect. This reduces the influence of the insulator layer 4 serving as a lower dielectric, and hence improves the characteristics.

FIG. 7A is a plan view showing another example of a spiral inductor (high frequency passive element) according to Embodiment 1 of the invention, viewed from the above. FIG. 7B is a sectional view taken along line E-E′ of FIG. 7A.

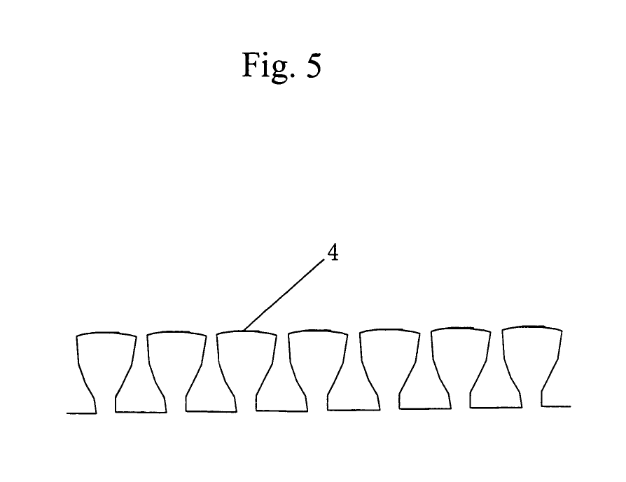

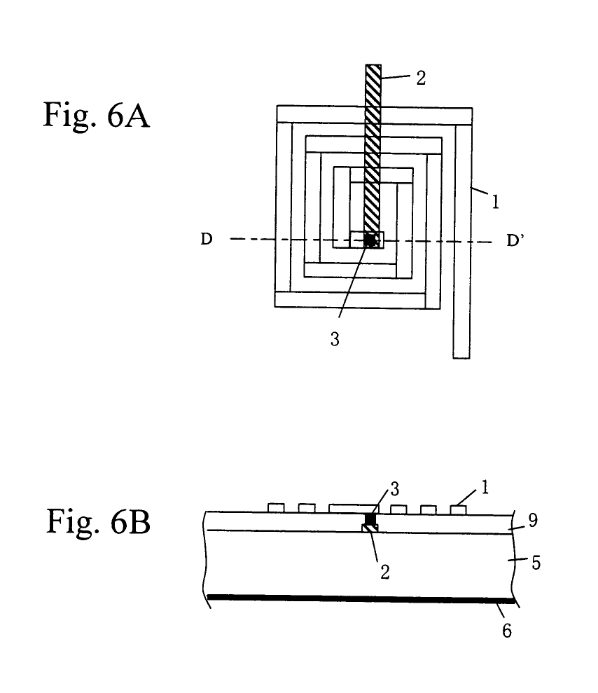

In the present embodiment, when the material, the temperature, the time, and the like used in the wet etching are selected appropriately, the insulating ridges are formed in a cross sectional shape of an inverted trapezoid such that the tip portion is wide and the pedestal portion is narrow, as shown in FIG. 5. This improves the retention adhesion property of the inductor conductor layer constituting the spiral inductor. Further, this configuration reduces the influence of the insulator layer serving as a lower dielectric, and hence improves the characteristics.

The insulating ridges may be formed by deposition of Si nano crystals, SiGe, or the like or by laser abrasion. After that, selective etching may be used so that the same configuration is obtained.

In the high frequency passive element of the present embodiment, a generally used substrate is employed that has a resistivity of approximately 0.1-100 Ωcm. However, a substrate having a higher resistance may be used.

The present embodiment has been described for the case of a spiral inductor. However, a straight line or a meander line can also be formed on an insulator layer composed of insulating ridges or insulating protrusions similarly to the case of the spiral inductor, so that the same effect is obtained.

### Embodiment 2

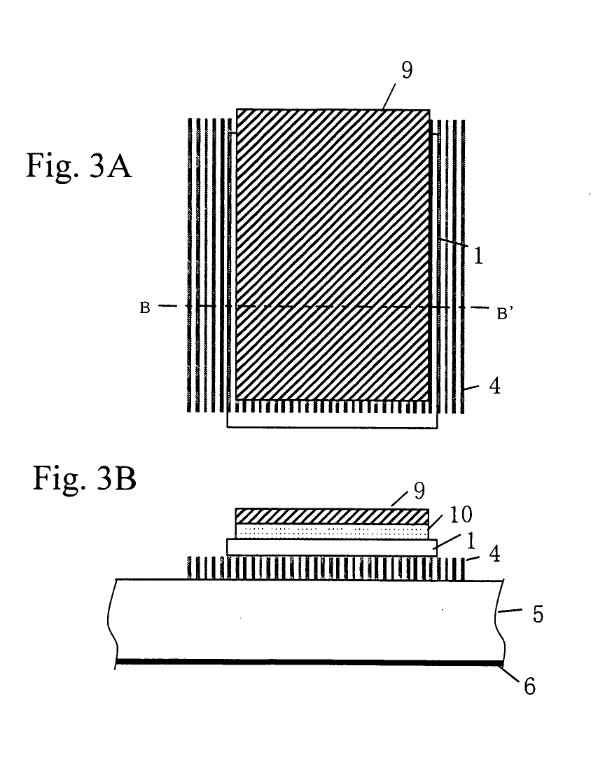

Embodiment 2 of the invention is described below in detail with reference to FIGS. 3A and 3B.

FIG. 3A is a plan view showing an example of an MIM (metal-insulator-metal) capacitor (high frequency passive element) according to Embodiment 2 of the invention, viewed from the above. FIG. 3B is a sectional view taken along line B-B′ of FIG. 3A.

As shown in FIGS. 3A and 3B, in this MIM capacitor, an insulator layer (insulation film) 4 composed of a SiN layer is formed on the principal surface of a Si substrate 5. A capacitor lower electrode (capacitor electrode conductor layer) composed of Ti/Pt/Au is formed as a first wiring metal layer 1 on the insulator layer 4 by vapor deposition. An insulation film (capacitor dielectric layer) 10 composed of a SiN layer is formed on the first wiring metal layer 1. A capacitor upper electrode (capacitor upper electrode conductor layer) is formed as a second wiring metal layer 9 on the insulation film 10 by Au sputtering. The capacitor upper electrode composed of the second wiring metal layer 9 and the capacitor lower electrode composed of the first wiring metal layer 1, together with the insulation film 10, constitute a capacitor.

The insulator layer 4 is composed of a large number of line-shaped insulating ridges formed with predetermined mutual spacing on the Si substrate 5. These insulating ridges are arranged in parallel to each other.

The present embodiment has been described for the case of a MIM capacitor formed on the Si substrate 5. However, the MIM capacitor may be formed on another semiconductor substrate (such as SiGe, GaAs, and GaN), a ceramic substrate (such as alumina), or a resin substrate.

In the present embodiment, the capacitor lower electrode and the capacitor upper electrode are composed of metallic wirings such as Ti/Pt/Au and Au. However, another conductor metal may be used so that the same effect is obtained.

Similarly, the insulator layer 4 may be composed of another dielectric material so that the same effect is obtained.

In the present embodiment, the insulating ridges are arranged in parallel to each other. When the insulating ridges are arranged in a radial manner extending from the center portion of the high frequency passive element toward the periphery, a disturbance is reduced in the electromagnetic field in the insulator layer serving as a lower dielectric, so that the characteristics is improved.

In the present embodiment, the insulating ridges are arranged in parallel to each other. However, similarly to the configuration of FIGS. 7A and 7B, the insulating ridges may be formed along an end face of the metal thereon with maintaining a predetermined distance from the end face of the metal. When constructed in this manner, the insulating ridges are kept away from a portion where the electric field is concentrated owing to a skin effect. This reduces the influence of the insulator layer serving as a lower dielectric, and hence improves the characteristics.

In the present embodiment, when the material, the temperature, the time, and the like used in the wet etching are selected appropriately, the insulating ridges are formed in the shape of an inverted trapezoid such that the tip portion is wide and the pedestal portion is narrow, as shown in FIG. 5. This improves the retention adhesion property of the capacitor lower electrode constituting the MIM capacitor. Further, this configuration reduces the influence of the insulator layer serving as a lower dielectric, and hence improves the characteristics.

The insulating ridges may be formed by deposition of Si nano crystals, SiGe, or the like or by laser abrasion. After that, selective etching may be used so that the same configuration is obtained.

In the high frequency passive element of the present embodiment, a generally used substrate is employed that has a resistivity of approximately 0.1-100 Ωcm. However, a substrate having a higher resistance may be used.

### Embodiment 3

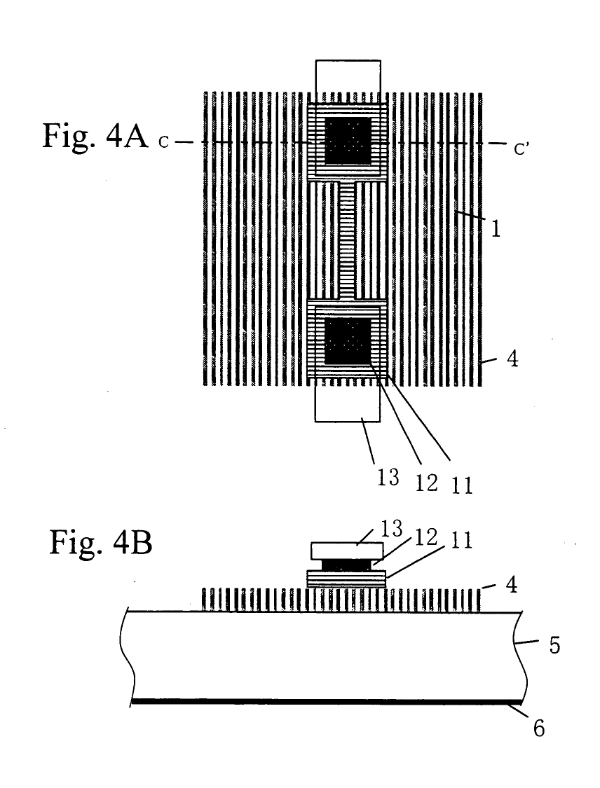

Embodiment 3 of the invention is described below in detail with reference to FIGS. 4A and 4B.

FIG. 4A is a plan view showing an example of a resistor (high frequency passive element) according to Embodiment 3 of the invention, viewed from the above. FIG. 4B is a sectional view taken along line C-C′ of FIG. 4A.

As shown in FIG. 4, in this resistor, an insulator layer (insulation film) 4 composed of a SiN layer is formed on the principal surface of a Si substrate 5. A metal body 11 such as Au serving as a resistor is formed on the insulator layer 4. On this metal body 11 serving as a resistor, an outgoing wiring (outgoing wiring conductor layer) 13 is formed by Au sputtering. The outgoing wiring 13 and the metal body 11 serving as a resistor are mutually connected through a contact hole 12.

The insulator layer 4 is composed of a large number of line-shaped insulating ridges formed with predetermined mutual spacing on the Si substrate 5. These insulating ridges are arranged in parallel to each other.

The present embodiment has been described for the case of a resistor formed on the Si substrate 5. However, the resistor may be formed on another semiconductor substrate (such as SiGe, GaAs, and GaN), a ceramic substrate (such as alumina), or a resin substrate.

In the present embodiment, a resistor conductor layer is composed of a metallic wiring such as Au. However, another conductor metal may be used so that the same effect is obtained.

Similarly, the insulator layer 4 may be composed of another dielectric material so that the same effect is obtained.

In the present embodiment, the insulating ridges are arranged in parallel to each other. When the insulating ridges are arranged in a radial manner extending from the center portion of the high frequency passive element toward the periphery, a disturbance is reduced in the electromagnetic field in the insulator layer serving as a lower dielectric, so that the characteristics is improved.

In the present embodiment, the insulating ridges are arranged in parallel to each other. However, similarly to the configuration of FIGS. 7A and 7B, the insulating ridges may be formed along an end face of the metal thereon with maintaining a predetermined distance from the end face of the metal. When constructed in this manner, the insulating ridges are kept away from a portion where the electric field is concentrated owing to a skin effect. This reduces the influence of the insulator layer serving as a lower dielectric, and hence improves the characteristics.

In the present embodiment, when the material, the temperature, the time, and the like used in the wet etching are selected appropriately, the insulating ridges are formed in a cross sectional shape of an inverted trapezoid such that the tip portion is wide and the pedestal portion is narrow, as shown in FIG. 5. This improves the retention adhesion property of the capacitor lower electrode constituting the resistor. Further, this configuration reduces the influence of the insulator layer serving as a lower dielectric, and hence improves the characteristics.

The insulating ridges may be formed by deposition of Si nano crystals, SiGe, or the like or by laser abrasion. After that, selective etching may be used so that the same configuration is obtained.

In the high frequency passive element of the present embodiment, a generally used substrate is employed that has a resistivity of approximately 0.1-100 Ωcm. However, a substrate having a higher resistance may be used.

### INDUSTRIAL APPLICABILITY

A high frequency passive element according to the invention has an effect of reduction of a parasitic capacitance, and is advantageously built in an MMIC or the like.

1. A high frequency passive element comprising: a substrate; an insulator layer composed of a single number or a plurality of insulating ridges or a plurality of insulating protrusions formed with predetermined mutual spacing on said substrate; and a passive element layer formed on said insulator layer.

2. A high frequency passive element according to claim 1, wherein said passive element layer is composed of an inductor conductor layer formed in a spiral or swirl pattern on said insulator layer.

3. A high frequency passive element according to claim 2, comprising: an outgoing wiring conductor layer provided between said substrate and said insulator layer; and a via hole provided in said insulator layer immediately under a center-side end portion of the spiral or swirl of said inductor conductor layer; wherein the center-side end portion of the spiral or swirl of said inductor conductor layer is connected to said outgoing wiring conductor layer through said via hole.

4. A high frequency passive element according to claim 2, wherein a single number or a plurality of said insulating ridges or a plurality of said insulating protrusions constituting said insulator layer are arranged in a radial manner extending from a center of the spiral or swirl of said inductor conductor layer toward a periphery.

5. A high frequency passive element according to claim 2, wherein a single number or a plurality of said insulating ridges or a plurality of said insulating protrusions constituting said insulator layer are formed along an end face of said inductor conductor layer with maintaining a predetermined distance from the end face of said inductor conductor layer.

6. A high frequency passive element according to claim 1, wherein said passive element layer comprises: a capacitor lower electrode conductor layer formed on said insulator layer; a capacitor dielectric layer formed on said capacitor lower electrode conductor layer; and a capacitor upper electrode conductor layer formed on said capacitor dielectric layer.

7. A high frequency passive element according to claim 6, wherein a single number or a plurality of said insulating ridges or a plurality of said insulating protrusions constituting said insulator layer are arranged in a radial manner extending from a center of said capacitor lower electrode conductor layer toward a periphery.

8. A high frequency passive element according to claim 6, wherein a single number or a plurality of said insulating ridges or a plurality of said insulating protrusions constituting said insulator layer are formed along an end face of said capacitor lower electrode conductor layer with maintaining a predetermined distance from the end face of said capacitor lower electrode conductor layer.

9. A high frequency passive element according to claim 1, wherein said passive element layer is composed of a resistive conductor layer formed on said insulator layer.

10. A high frequency passive element according to claim 9, wherein a single number or a plurality of said insulating ridges or a plurality of said insulating protrusions constituting said insulator layer are arranged in a radial manner extending from a center of said resistive conductor layer toward a periphery.

11. A high frequency passive element according to claim 9, wherein a single number or a plurality of said insulating ridges or a plurality of said insulating protrusions constituting said insulator layer are formed along an end face of said resistive conductor layer with maintaining a predetermined distance from the end face of said resistive conductor layer.

12. A high frequency passive element according to claim 1, wherein a single number or a plurality of said insulating ridges or a plurality of said insulating protrusions constituting said insulator layer have such a cross sectional shape that a pedestal portion is narrow and that a tip portion is wide.

13. A high frequency passive element according to claim 1, wherein a single number or a plurality of said insulating ridges or a plurality of said insulating protrusions constituting said insulator layer are formed from Si nano crystals.
